(19) United States
(12) Patent Application Publication
(10) Pub. No.: US 2008/0124657 A1
(43) Pub. Date: May 29, 2008

(54) Method of Making a Photopolymer Plate

(76) Inventors: Paul Mayo Holt, Uppingham (GB); Robert Paul Filik, Corby (GB)

Correspondence Address: KOLISCH HARTWELL, P.C., 520 SW YAMHILL STREET, Suite 200, PORTLAND, OR, 97204, US

(21) Appl. No.: 11/795,943

(22) PCT Filed: Jan. 23, 2006
(86) PCT No.: PCT/GB06/00216

§ 371 Date: Jul. 24, 2007

Related U.S. Application Data
(60) Provisional application No. 60/693,278, filed on Jun. 22, 2005.

(30) Foreign Application Priority Data
Jan. 25, 2005 (GB) 0501440.2

(51) Int. Cl. G03F 7/26; C08F 2/46

(52) U.S. Cl. 430/309; 522/64; 430/300

(57) ABSTRACT

This invention describes an exposure apparatus comprising a light measuring device and a light transmitting clamp designed to compress a photocurable (photopolymer) package for use in manufacture of a hand stamp plate, the package typically consisting of a sachet containing a liquid photopolymer. The liquid photopolymer is specifically engineered to cure under ambient lighting conditions eliminating the requirement for fluorescent tubes to create the UV light to cure the photopolymer. The light measuring device is designed to inform the user of the required exposure time for the printing plate.

### BACKGROUND

The present invention relates to a system for exposing a photocurable liquid polymer to produce a printing plate.

Up until now it has always been necessary to irradiate photocurable liquid polymer (or photopolymer) in an exposure unit, which produces UV radiation generated from actinic fluorescent tubes.

The previous commonly used technique for making photopolymer printing plates for hand stamps is as follows: a masking element (in practice a photographic negative) is placed on a horizontal glass support forming the base of an exposure unit. The exposure unit is a device for irradiating liquid photopolymer with ultra violet light to cause the liquid to cure. A transparent plastic cover sheet is then placed over the masking element and any entrapped air between the masking element and the cover sheet is evacuated. A containment wall is adhered to the cover sheet to form a reservoir or tray in which the liquid photopolymer will be contained. The liquid photopolymer is then poured into the tray defined by the containment wall to substantially fill the reservoir to its top. Indeed, it is preferably filled sufficiently for a convex meniscus to rise above the containment wall as any overfilled polymer will be forced over the containment wall, whereas an under-filled reservoir would produce a thin plate of poor image. A semi-rigid backing sheet that has been coated with a compound containing a photo-initiator is then carefully laid over the liquid photopolymer, avoiding entrapping air bubbles. This assembly of photopolymer is then irradiated with UV radiation from above, to form a continuous cured polymer layer supporting the printing surface (a floor), and then from below, through the masking element or negative, for imagewise curing of the photopolymer to form the printing surface. The cured plate is removed and uncured resin is washed out from the unexposed areas using warm water and a detergent. The plate is then post exposed by irradiating it once again under the UV light source, typically under water (to prevent oxygen from inhibiting the curing reaction). The plate is removed, dried and is ready for use.

In 2002 a new method of stamp manufacture was commercialised that removed the necessity to assemble and fill a reservoir; instead it provided the user with the liquid polymer in a pre-packaged form. The conventional method of assembling a printing plate could therefore be replaced by simply utilising a pre-filled quantity of photopolymer sealed within a plastic container.

There are a now a few different types of pre-packaged photopolymer container available for the user. What follows is a summary of the development of this concept and the currently available products.

The commercial market for this product was opened by Photocentric Ltd. of 28-29 Maxwell Road, Peterborough, United Kingdom with their product imagepac (imagepac is a registered trade mark). imagepac is a plastic sachet containing photopolymer, where the plastic comprising the sachet is removable from both sides of printing plate after irradiation with light. imagepac is widely used for hand stamp manufacture and in 2004 became the most commonly used method of manufacture of business stamps in the UK. imagepac is covered by UK patent GB2372575 and U.S. Pat. No. 6,737,219, whilst a European patent application 02755145.6 and U.S. patent application Ser. No. 10/776,987 are pending.

The patent documents mentioned in the previous paragraph describe a package which consists of a sachet and a photocurable preparation in the sachet. The claimed package is exclusively for use in making hand stamps and is further characterised by the absence of any element to form a backing sheet. The patent documents further describe the package as follows:

The package may be made by a process wherein a sachet is filled with a curable liquid resin in the absence of a future backing sheet, after which the sachet is irradiated to cure the resin, the outer walls of the sachet are removed, and the contents are washed to remove uncured resin in non-irradiated areas.

The preferred mode of forming the photopolymer package envisages the introduction of photopolymer into the sachet, this then being allowed to settle, causing the sides of the sachet to distend slightly after filling, such that the sachet is not completely full; a vacuum is then applied to draw the sides of the sachet together above the photopolymer surface, and the sides are then sealed to each other at this region where they are drawn together. The empty sachet may optionally be formed as an envelope, from a sheet or sheets of material, as the first stage of the manufacture of the photopolymer package. Preferably, however, it is supplied as a pre-formed pouch, which is then filled with the photopolymer prior to sealing. In either case, the empty sachet, which is itself an aspect of the invention, typically comprises a rectangular package, sealed on three sides, with the fourth side open to allow for filling of the sachet.

After the photopolymer has been cured, therefore, the sachet is stripped from the cured resin to provide a resin plate without a backing sheet.

The walls of the sachet are made of plastics material. Whilst a wide range of such materials is suitable for use in the context of the present invention, it is necessary that the material selected should possess two properties inherent in photopolymer systems: in the first instance, it is clearly a requirement that the material should allow for a high degree of transmittance of curing radiation, e.g. UV-radiation and in normal practice actinic radiation, since the photopolymer in the package is normally UV-cured; secondly, the radiation which is transmitted should pass through the material without being seriously diffracted. Further, it is desirable that the material should have a high degree of resistance to creasing, otherwise the sachet will have to be handled with great care.

Conveniently the plastics material is a polyolefin material or a polyolefin laminate. The polyolefin is typically polyethylene or a polyethylene copolymer or polyethylene blend. Nylon® and other normal polyamide materials are found to diffract light, but orientated polyamides (OPA) do transmit light and may be used. Preferably, the plastics material (plastics film) is a laminate. Optionally, the plastics film may be surface treated, but it is preferred that untreated plastics material should be employed. Particularly favourable results have been achieved using a polyethylene/polyethylene terephthalate laminate material. In such commercially available materials, the layers of the two plastics are bonded together by means of an adhesive interlayer.

A further parameter which must be considered in relation to the three properties specified above is the thickness of the plastics material. Thus, it is found that increasing thickness leads to improvements in terms of crease resistance, but is also associated with reductions in light transmittance. Conversely, thinner films give a high level of light transmittance, but show an increased tendency towards creasing.

Consequently, a preferred range of thickness for any given plastics material should be established, in order that all aspects of performance may be optimised. It has also been found that for optimum performance, the larger the sachet is, the thicker the film should be. This can be seen as, in effect, achieving a constant ratio of film thickness to film area, maintaining the rigidity of the package at a constant level. However, very thick films provide a stronger apparent adhesion to the cured film than thinner films, and this has proved to be a problem with thinner plates when removing the film, because the plate tends to pull away in parts not in whole. Whereas thicker films (typically at 160 μm and above) can be used with thicker plates (typically above 4 mm in depth), when used on thinner plates they exert too much force when being removed. The industry standard thickness of plate is 2.3 mm, and experiments indicate that, for commercially acceptable performance, the maximum thickness of film that can be used with such plates is 90 μm, or thereabouts.

More generally, it may be stated that the sachets are desirably made of plastics material that has a thickness of from 30 to 180 μm, and more preferably of from 70 to less than 110 μm. Hence, for the polyethylene/polyethylene terephthalate laminate material previously mentioned, it has been found that thicknesses above about 180 μm are associated with unacceptably low light transmittance levels and a bad image, whilst creasing becomes a major problem when the thickness falls below around 30 μm. Preferably, in particular for a sachet of A5 size, the laminate is at least 60 μm, and more preferably at least 70 μm, thick. More usually, it is between 75 and 90 μm thick, in particular but not exclusively for A5 size sachets. Optimum levels of performance for a sachet of this size appear to be achieved with this particular plastics material when it comprises a 70 μm film of polyester laminated to a 12 μm film of polyethylene terephthalate, giving an overall thickness in the region of 82 to 85 μm. At this thickness, the level of light transmittance is found to be approximately 85%. It is believed that the thickness of inter lamina adhesive layers is typically about 3 μm.

In the case of hand stamps, liquid photopolymer preparation may comprise any photopolymer preparation of band stamp quality, as will be well known to the skilled person. Advantageously, a preparation of relatively low viscosity is used, as this aids filling. There may be mentioned liquid photopolymers having a viscosity between the range of 2,000-50,000 cps, more usually 2,000-35,000 cps. Typical liquid photopolymers which may be used to make hand stamps or other polymer printing plates include, for example, unsaturated polyurethane resins, e.g. polyether urethane polymers, or polyether polyester urethane copolymers such as, for example, polyether polyester urethane methacrylate polymers. As suitable polymers for use in making polymer printing plates may be mentioned those which when cured have a Shore A durometer hardness of no more than about 55; in particular, photopolymer compositions for use in making hand stamps more typically have a Shore A durometer hardness of about 45-55.

The liquid photopolymer will in commercial practice include a photoinitiator in the known way. Such conventional photoinitiators are typically organic carbonyl compounds

Additionally, the resin preparation may contain any one or more of a range of further performance-enhancing additives including, for example, esters of acrylic or methacrylic acid, stabilisers, defoamers, dyes and high molecular weight fatty acids; the fatty acids, for example myristic acid, are particularly effective in ensuring a dry, tack-free surface after post-curing of the washed plate. However, it is found that the presence of myristic acid in the photopolymer package can result in a degree of cloudiness; whilst this is not detrimental to the performance of the package, it is considered to be cosmetically undesirable, and it is contemplated that the presence of this material could be avoided.

The aforementioned patent documents describe a method for forming a photopolymer package for use in making a hand stamp which comprises: providing an envelope which comprises a pre-formed pouch to contain the photocurable liquid polymer, the pouch being formed from a sheet or sheets, both of which can be released from the cured photopolymer, and having a mouth formed between adjoining portions of the sheet or sheets to receive the liquid curable polymer; introducing the photocurable liquid polymer into the pouch by way of the mouth of the pouch to fill the pouch to a level less than its capacity; applying a vacuum to draw the sides of the pouch together above the level of the photopolymer; and then sealing the adjoining portions of the sheet or sheets together to form a package consisting of a sealed sachet and said polymer.

After filling the pouch with the photopolymer, the mouth of the pouch is sealed by suitable means, preferably by thermosealing.

The aforementioned patent documents further describe a method for forming a photopolymer package for use in making a hand stamp, the method being a form-fill-seal process which comprises: forming an envelope to contain the photocurable liquid polymer from a sheet or sheets, both of which can be released from the cured photopolymer, the envelope having a mouth formed between adjoining portions of the sheet or sheets to receive the liquid curable polymer; introducing the photocurable liquid polymer into the envelope by way of the mouth of the envelope to fill the envelope; and then sealing the portions of the sheet or sheets together (i.e. sealing the opposed sides of the envelope together) to form a package consisting of a sealed sachet and said polymer. The invention thereby includes a method in which a photopolymer package for use in making a hand stamp is made by a method consisting essentially of a form-fill-seal technique using a sheet or sheets, neither of which adheres to the cured resin.

Also described is a form-fill-seal process for forming a photopolymer package for use in making a hand stamp, in which the photocurable liquid polymer is introduced into the envelope by way of the mouth of the envelope to fill the envelope beyond its capacity; and then the opposed sides of the envelope are sealed together through the excess photopolymer to form a package consisting of a sealed sachet and said polymer.

It is described that, when overfilling is used, standard polyolefin sheeting is workable. However, the mouth portions of the sheet or sheets may be specially selected to facilitate thermosealing together despite the presence between those portions of fats present in commercial liquid photopolymer preparations, as a result of overfilling the envelope. The presence of these fats can have a deleterious effect on the thermosealability of the mouth portions if standard polyolefin sheeting is used. The fats are those present in a typical curable liquid photopolymer such as an unsaturated polyester urethane methacrylate and/or polyether polyester urethane methacrylate polymer, ethylenically unsaturated monomers such as esters of acrylic acid and/or methacrylic acid and a photopolymerisation initiator. A suitable adapted transparent plastics sheet material is Rocklid (Trade Mark) or Rockseal-O (Trade Mark) of Rockwell Solutions Limited. Rockseal-O in particular is specially designed to thermoseal through fats and oil.

Further described is a form-fill-seal process for forming a photopolymer package for use in making a hand stamp, in which the photocurable liquid polymer is introduced into the envelope by way of the mouth of the envelope to fill the envelope to a level less than its capacity; a vacuum is applied to draw the sides of the envelope together above the level of the photopolymer; and then the sides of the envelope are sealed together to form a package which consists of a sealed sachet and said polymer.

As in the case of the pre-formed envelope, formation of the envelope as a stage in the form-fill-seal procedure may involve the use of either one or two sheets of plastics material, but envelopes formed from two sheets are preferred. In the case wherein the envelope is produced from a single sheet of material, the sheet is folded in half and the two sides adjacent the fold are sealed, preferably by thermosealing, leaving the side of the envelope opposite the folded side open for filling with photopolymer. When two rectangular sheets of plastics film are employed, the sheets should be of equal size; one is placed on top of the other and the assembly is sealed on three sides, again leaving an envelope with one open side, forming a mouth through which filling with photopolymer can take place. Sachets formed from a single rectangular sheet of material include three sides which are sealed, the fourth side comprising a fold, whereas the preferred sachets, formed from two rectangular sheets of material, are sealed on all four sides.

The liquid photopolymer is introduced into the open mouth of the pouch or envelope for example by pouring or injecting. The photopolymer may be heated to around 50-60° C. to decrease its viscosity and thereby facilitate greater ease of transfer to the pouch or envelope; removal of air and other gases from the photopolymer whilst under vacuum is also made easier by raising the temperature in this way. The sealing operation may then take place, preferably using any of the standard thermosealing techniques well known to those skilled in the art.

A preferred method comprises forming a photopolymer package for use in making a hand stamp wherein a pouch is pre-formed from two sheets of identical plastics film. Production of the sealed sachet forming the photopolymer package from the said pouch may then be achieved by either manual or automated means. Thus, the pre-formed pouch may be manually filled by pouring or injecting the photopolymer, or a pump or gravimetric/peristaltic system may be used, and the pouch can then be sealed by means of a heated bar in a vacuum chamber; commercially available vacuum packing apparatus, such as the Multivac® C400, may conveniently be used for the latter purpose. Typically, the pouch is held under vacuum for 1-2 minutes to allow the sealing process to be completed.

Alternatively, an automated procedure may be employed, wherein a succession of pre-formed pouches are mounted in line, vacuum filled (usually individually) with photopolymer, then either individually vacuum sealed by application of a local vacuum to each envelope in turn or, more preferably, bulk sealed by introducing a multiplicity of filled envelopes into a vacuum chamber prior to performing the sealing operation. In any event, the photopolymer is allowed to settle in the pouch, causing the sides to bulge slightly after filling, prior to drawing together the adjacent sides at the open end and sealing, preferably by thermal means.

During the vacuum application stage of these procedures, when the adjacent sides of the sachet are drawn together prior to sealing, it has been observed that significant foaming of the photopolymer is prone to occur if the vacuum that is applied is too great, typically in excess of 700 mbar. As this foaming effect is deleterious it is preferable to keep the vacuum level low, sufficient only to remove air above the resin but not sufficient to cause foaming. For practical reasons, it is not realistic when using high vacuum to continue the procedure until foaming totally ceases since this would be excessively time-consuming.

As previously discussed, a wide variety of thermoplastic and heat-sealable materials may be used for the formation of sachets, suitable examples including polyethylenes and various laminates. The nature of the material determines the particular heat-sealing technique which is employed, but these will generally involve the application of heat and pressure. Many thermoplastics are sealed by means of impulse sealing, wherein a charge of electricity heats a wire to a pre-established temperature, and no specific tooling pressure is required.

As previously observed, in addition to the use of a pre-formed pouch for the production of the photopolymer package, a form-fill-seal technique may be used to produce an envelope suitable for such purpose. Two principal form-fill-seal techniques are known, namely horizontal form-fill-seal (HFFS) and vertical form-fill-seal (VFFS). HFFS is used for a variety of products and, as the name suggests, involves the material forming the sachet travelling in a horizontal plane. Typically, the material is dispensed from a roll and is pulled forward and folded to form a tube, whereupon the side opposite the fold is heat-sealed. Subsequently, the ends are sealed, the back seal on one pouch forming the front seal on the next, and the resulting sachet is cut free. Filling of the sachet is achieved by cutting it open and inserting the relevant product by top-filling, following which the sachet is resealed.

Clearly, the cutting open and resealing procedure generally associated with HFFS represents a drawback of the technique, and it would be advantageous if the sachet could be filled prior to final sealing. This is possible by means of VFFS, wherein a web of material is driven or pulled down vertically, wrapped round a collar to form a tube and the side opposite the fold is sealed, as with HFFS. Alternatively, the web of material may be cut in two and the two strips in generally vertical orientation are then presented face to face with both sides requiring sealing in order to form the requisite tube. Thereafter, the bottom end of the tube, which will form one end of the sachet, is sealed. Filling of the sachet with the relevant product then takes place, after which the top of the sachet is sealed, this seal simultaneously forming the bottom of the next sachet, with the lower formed and filled sachet being cut free from the upper sachet at this stage. Conveniently, the filler device (fill tube) may be mounted directly above the tube forming section.

The aforementioned patent documents describe how it had been found that commercial automatic VFFS sachet packaging machines are suitable for the formation of photopolymer packages. In particular, those machines which cut a web of material into two sheets, then bring these sheets face to face and seal them together, have been utilised with success.

Thus, a reel of plastics material is fed through the machine until it reaches a blade which slits the material into two equal sections. The separate sections are split off in opposite directions at 90° to the reel through a film divider unit. The inner sides of the two sections of plastics material are then positioned to vertically face each other and brought together in order that the bottom and sides may be heat sealed to form an open sachet.

The dosage of photopolymer required to be present in a single sachet is then introduced into the sachet by means of an appropriately located fill tube connected to a pump or gravimetric/peristaltic system. The operation is carried out under vacuum in order to eliminate air although, as previously disclosed, it is not essential to the performance of the invention that all air should be removed in every case, which is not true of the methods of the prior art.

Following the initial dosing procedure, the top seal of the sachet is formed by heat-sealing, this seal also forming the bottom seal for the next sachet in the continuous web of plastics material. The side seals of the next sachet are formed at the same time, thereby beginning the cycle again, the next sachet being filled in the manner previously described. The individual sachets are then cut off from each other by means of a slitter.

Thus is provided a continuous method for the production of photopolymer packages according to the method of the invention.

The automatic sachet packaging machines of this type may be used to pack into sachets viscous liquid products in volumes from 1 ml to 250 ml. The optimum dose of photopolymer for the purposes of the invention is determined by the size of the photopolymer package which is to be manufactured.

Other types of pre-filled sachets of photopolymer exist in a handed format, that is a product which has two differing sides. This type of product has a rigid side that is coated with photoinitiator to adhere to the photopolymer when exposed to UV light and a non-coated side that is placed on top of the photographic negative. imagepac xtra, manufactured by Photocentric Ltd. of 28-29 Maxwell Road, Peterborough, United Kingdom is a product of this type. imagepac xtra is a plastic sachet containing photopolymer, where the two walls are of dissimilar type, one side being rigid and coated with a photoinitiator compound which ties to the photopolymer when irradiated through the floor of the plate, the other side being flexible and imbued with excellent light transmission properties. This product will produce a hand stamp incorporating an integrated backing sheet for the base of the printing plate. imagepac xtra is used for the manufacture of hand stamps around the world.

This description of different methods of pre-packaging photopolymer is by no way limiting. This invention however requires for convenient performance the use of a pre-packaged photopolymer in some format, although the use of prepackaged photopolymer is not as such an element of the invention.

The most common design for a liquid polymer exposure unit is a box containing a light source, typically fluorescent tubes, which irradiates the photopolymer package which is held compressed between two glass sheets of a clamp. Typically machines used to make hand stamps either have one set of fluorescent bulbs in which the user reverses the clamp to irradiate the other side of the photopolymer plate, or machines which have two sets of bulbs, one above the glass clamp and one below, which can irradiate both sides of the photopolymer plate. Whereas machines may vary in their complexity and the level of sophistication, the basic principle of a bank of fluorescent tubes irradiating the photopolymer on both sides remains unchanged from the smallest stamp machine to the largest flexographic exposure unit.

### BRIEF SUMMARY OF THE DISCLOSURE

This invention provides in one aspect an exposure apparatus that uses ambient light instead of UV radiation produced by fluorescent tubes or another UV source. The exposure apparatus is therefore adapted to expose a liquid photopolymer to ambient light to cause the photopolymer to cure to form a printing plate.

This provides the advantage that the exposure unit is considerably cheaper to manufacture, operate and maintain. By this virtue it opens hand stamp manufacture up to a considerably wider market.

The invention also provides a liquid photopolymer preparation adapted to cure under ambient light. Liquid photopolymer preparations for use in making polymer printing plates, for example hand stamps, are typically free of colouring agents which may be included in coating materials, for example. The photopolymer may include a photoinitiator that is activated at wavelengths of greater than 350 nm and more typically at wavelengths of 370 nm or more. Included are liquid photopolymer preparations containing as a photoinitiator an aromatic phosphine oxide, and more specifically a bis-acylphosphineoxide. Further included are pre-filled photopolymer sachets containing such photopolymer preparations. They also usually have the characteristics previously mentioned, for example the polymer is typically an unsaturated polyurethane and the cured resin typically has a Shore A hardness of no more than about 55.

The invention includes exposure apparatus which is adapted to use ambient light to cure photocurable liquid photopolymer to form a polymer printing plate. The apparatus does not include a source of curing radiation but does allow ambient light to reach the polymer. In an embodiment, the exposure apparatus comprises two plates of light transmitting material adapted to releasably hold between them a photopolymer container, usually in a clamping arrangement in which the plates are substantially parallel with each other. The exposure unit does not include lamps or other irradiation apparatus to promote curing of photopolymer (but may of course include lights for the purpose of, e.g., indicating the status of a timer unit described later in this application).

Also included in the invention is a method of curing liquid photopolymer to form a printing plate, comprising exposing the liquid photopolymer to ambient light. In typical practice, the method comprises:

uniformly exposing a first face of a liquid photopolymer container to form a floor; and then

imagewise exposing a second face of the liquid photopolymer container to form a printing surface.

The method typically further comprises one or more additional steps to make an end product printing plate, hand stamp or print roller, including one or more of wash out, post-exposure, drying and hand stamp assembly.

The term “uniformly exposing” means that a masking element or photographic negative is not laid over the photopolymer container to cause imagewise curing. Usually, the photopolymer container is supported on a substantially horizontal surface, for example of a desk or table, such that it has an upper face exposed to ambient light to cause curing; in the first step, a first, upper, face is of course free of any masking element and, after completion of the first step, the container is inverted to expose a second, opposed face, which has a masking element placed over it.

The exposure process will usually be performed whilst a preformed photopolymer package is held between opposed light transmitting plates, e.g. glass plates, the masking element (in current practice a photographic negative) being placed between one of the glass plates and the preformed package.

In order to obtain a good quality product, it is necessary to monitor the intensity of the light to which the liquid photopolymer is exposed and thereby to determine an appropriate exposure time. The invention therefore provides exposure apparatus which includes light intensity measuring apparatus; the apparatus may further include a timer device operably connected to the measuring apparatus and to signal producing apparatus, the timer actuating the signal producing apparatus when a suitable time has elapsed for exposing a face of the photopolymer package. The signal is suitably an audible signal.

It is envisaged that pre-packaged photopolymer will be used, the alternative to this being the pouring of liquid photopolymer. It is not convenient to use poured liquid photopolymer in this ambient light exposure method for a number of reasons, namely i) the assembly process would take a protracted period of time, typically about 10 minutes, during which the photopolymer would—unless very slow curing—be curing from irradiation with the ambient light; ii) the mobility of the liquid photopolymer would allow it flow outside the confines of the damming wall so that, unless special measures were taken, the resin would run over the exposure unit when the exposure unit was inverted; iii) the method would require drawing of drawing vacuum to successfully remove air from between the plates and plastics sheeting interposed between the plates and the liquid polymer, preventing a good image from being formed.

Throughout the description and claims of this specification, the words “comprise” and “contain” and variations of the words, for example “comprising” and “comprises”, means “including but not limited to”, and is not intended to (and does not) exclude other moieties, additives, components, integers or steps.

### BRIEF DESCRIPTION OF THE DRAWINGS

FIG. 1 is a perspective view of an exposure unit falling within the invention;

FIG. 2 is a diagrammatic cross section through the exposure unit of FIG. 1 when in use; and

FIG. 3 is a block diagram illustrating a control system usable in the exposure unit of FIG. 1.

FIG. 4 is a circuit diagram of the whole timer device.

FIGS. 5A-D are circuit diagrams of the various components making up the timer device.

FIG. 5A is a UV photodetector circuit.

FIG. 5B is an oscillator circuit which is connected to a PIC controller of the timer device.

FIG. 5C is a battery circuit.

FIG. 5D is a voltage reference circuit.

### DETAILED DESCRIPTION OF SEVERAL EMBODIMENTS

In one aspect, the invention provides an exposure apparatus that uses ambient light to cure liquid photopolymer in the preparation of a polymer printing plate. The printing plate may be for a hand stamp; in other embodiments it may be for a rotary printing press, for example. The exposure apparatus in use has opposed faces between which the liquid photopolymer is placed at the start of the exposure process.

By the term “ambient light” is meant light which is not irradiated by a light source adapted to produce UV curing radiation but, rather, daylight or artificial light from ordinary electric lights used for illuminating a workplace or home, for example.

It is for good performance necessary that the faces of the ambient light exposure unit be rigid and capable of being arranged in planar parallel orientation, so that the photopolymer between the faces of the unit may in turn have opposed planar parallel surfaces. It will be appreciated that the faces of the unit may have limited flexibility and that they need not be absolutely planar parallel when the photopolymer is exposed; rather, the faces should be rigid and planar parallel to a sufficient degree to obtain a useful product. Thus, any exposure unit found to be capable of producing a vendible product will have adequate rigidity and orientation of its faces, however far they depart from true rigidity and true planar parallel orientation.

It is also necessary that these faces be made of material which has light transmitting properties. The ideal light transmitting properties can be defined as the optimisation of both total light transmitted and absence of light deviation when passing through the medium of the face. For a convenient exposure unit, it is necessary that the faces of the ambient light exposure unit allow a large proportion of incident light to be transmitted. For a good quality cured plate, the faces of the exposure unit should allow light through without considerable deviation (e.g. refraction), as deviation would impair the resultant image. Substantial deviation of light through the medium could lead to the creation of a broader printed image by virtue of an increase in the angle of incidence to the horizontal with which the light strikes the photopolymer.

Consequently, a preferred range of thickness for any given exposure unit face should be established in order that all aspects of performance may be optimised. Although rigid plastics can be used, desirably the material should be glass. Suitably, the glass is of from about 2 mm to about 12 mm thickness and often of from about 2 mm to about 10 mm thickness, e.g. about 2 mm to about 6 mm, more preferably ordinary glass of about 4 mm thickness was found to have a good combination of light transmission and light deviation for the faces for the exposure unit. Thus, glass having a thickness of about 3, 4 or 5 mm may be used.

As previously indicated, the exposure unit may be described as comprising clamp apparatus comprising two plates of light transmitting material adapted to releasably hold between them a photopolymer container. The container is usually held in a clamping arrangement in which the plates are substantially parallel with each other and entrapment of air between the sachet and the plates is avoided. The exposure unit is usually intended to produce hand stamp plates and, to that end, the plates are typically of approximately a standard paper size, e.g. an ISO paper size or US standard size (8½″×11″), for example they may be of about the following dimensions in millimetres, e.g. of the following dimensions ±10 mm, e.g. ±5 mm such as, for example, ±2 mm:

### A3 297×420

### A4 210×297

### A5 148×210

### A6 105×148.

In embodiments, the plates are of no greater than standard US paper size, or no greater than A3, A4, A5 or A6 size, in all cases ±10 mm, e.g. ±5 mm such as, for example, ±2 mm.

In an embodiment of the invention, the opposed faces of the exposure unit (i.e. opposed light transmitting plates) compressively clamp between them a preformed photopolymer package. The two exposure unit faces can be held in compression by at least one clamping device, e.g. by a clip or plurality of clips, for example one at each end of the exposure unit. In this case it is desirable to attach spacers or bearers to the faces to ensure appropriate and parallel spacing between the faces. These spacers will determine the final plate height. The exposure apparatus may therefore comprise two light transmitting (e.g. glass) plates and clip apparatus (e.g. a plurality of clips) to hold the plates together with a photopolymer package and a masking element between them. Spacer apparatus (e.g. a plurality of spacers) may be included. The clips and any spacers are adapted for the plates to be spaced apart by the desired amount, e.g. about 2.3 mm or a fraction more (e.g. 2.3-2.4 mm).

Alternatively these two faces can be held together with a hinge at one end of the unit, for example a piano hinge, and urged together by a clip or clamp at an opposed end of the unit. In this case no spacer may be required as the gap at the hinge side is fixed and the gap at the open side is determined by the depth of the clip. The size of the container of resin and the dimensions of the space defined between the closed faces of the exposure unit are such that the faces of the closure unit clamp the resin container in place when the clip or clamp is closed.

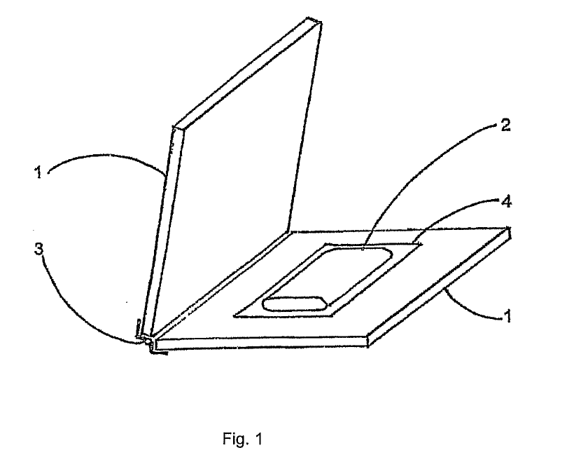

An embodiment of an exposure of the invention is illustrated in FIGS. 1 and 2. The exposure unit comprises two transparent plates 1, made of rigid material such as glass, for example. The perimeters of the plates may be enclosed by a frame around the entire perimeter or by a partial frame, for example members attached to two opposed side edges. It will be appreciated in general, therefore, that the plates 1 may have attachments not shown in the illustrated embodiment.

A hinge 3 connects the two plates 1 at one edge of the exposure unit. A masking element or negative 4 is shown on the bottom plate 1 and, lying on the negative, a pre-filled sachet 2 of liquid photopolymer.

FIG. 2 is a diagrammatic illustration of the exposure unit in use. The two plates 1 have been closed together and a clip or clamp 7 placed around the plates at the open end of the unit, to hold the plates 1 together so that they in turn clampingly hold the negative 4 and the sachet 2 in the unit.

Reference numeral 8 indicates a source of ambient light, whether it be a light bulb, as illustrated, or a window or other source of natural light, or otherwise. The light bulb is an ordinary light bulb of the type used to providing illumination in a home or business, and not a specialist UV light source.

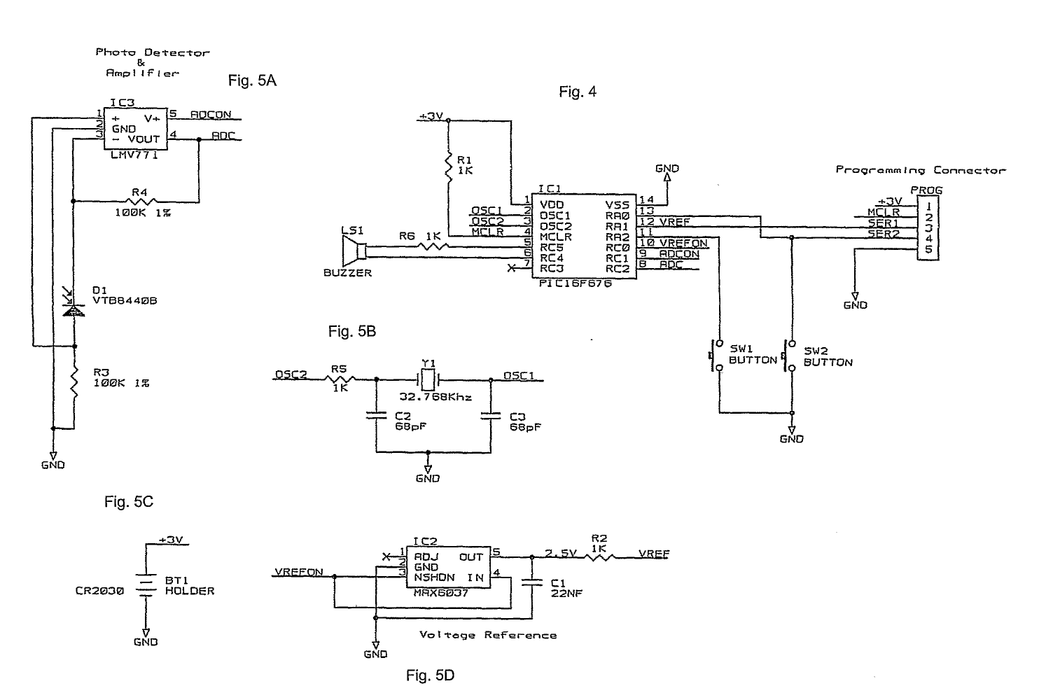

Also shown in FIG. 2 is a timer apparatus 6, comprising a UV photodetector 5. FIG. 4 is a circuit diagram of the timer device. FIG. 5A details the UV photodetector circuit.

In the orientation shown in FIG. 2, the upper face of the photopolymer sachet 2 is uniformly exposed to ambient light, that is to light from the sun or from an artificial source of visible light, such that the photopolymer cures to form a floor. When a floor has been formed, the arrangement must be inverted such that the unexposed, formerly lower, face of the sachet 2 is placed uppermost with the masking element 4 above it. The inversion is conveniently performed by turning over the entire exposure apparatus containing the sachet 2 and negative 4.

The upper surface of the photopolymer is cured imagewise by exposure to ambient light through the negative 4 to form a printing surface. Thereafter the sachet is opened and the plate washed out then dried, to form a printing plate, usually a hand stamp plate.

Ambient light, that is either sunlight or artificial light from lamps within buildings, contains UV radiation of varying wavelengths and varying intensities. The ambient light exposure unit is a mechanism for clamping a flexible photopolymer container such that it has opposed substantially planar parallel faces, whilst at the same time allowing ambient light to be transmitted to that container. For a good quality product, each face of the photopolymer container should be exposed to an optimum amount of light. An embodiment of this invention therefore includes light measuring apparatus, so that it may be determined when a suitable exposure time has been reached at which the requisite amount of ambient light has been transmitted through a respective face of the exposure unit to produce a suitably cured plate. Usually, the light measuring apparatus determines the exposure time and causes a signal to be produced when the exposure time has been attained.

In other words, whereas it would possible to expose a photopolymer container contained in a simple ambient light exposure unit, it would be difficult to make an excellent plate. It would be particularly difficult to judge the correct amount of light necessary to produce the required depth of plate floor. It is the case that ambient light varies considerably in intensity throughout the day and even varies throughout the period of a single exposure cycle. If it desired to obtain an excellent product, it is critical to govern the amount of light reaching the photopolymer in order to ensure an accurately obtained floor height, typically around 50% of the total plate height, and a relief that is neither over nor under exposed. For this reason it is a further embodiment of this invention that the apparatus includes a measuring device that can inform the user when the correct time has elapsed for the user to invert the assembly to expose the other side and then to open the container and to terminate the reaction. For good results, this electronic device must be situated adjacent to the face of the exposure unit so that it takes readings that are representative of the intensity of light that is reaching the plate. The apparatus may be made as a single unit which incorporates both the clamping plates and the timer, or the timer may be made as a separate unit from the clamp.

This electronic device suitably measures the intensity of light over a number of short time intervals (suitably every 1 sec) to calculate the correct exposure time for each side of the photopolymer container. Light may be measured using a photodiode capable of sensing emission in the UVA region of the electromagnetic spectrum, nominally 315 nm-400 nm. It was found that the ideal choice of photodiode was one doped to absorb in both the UV and visible regions of the electromagnetic spectrum.

The diode is linked to a counting processor. The photodiode measures the intensity, which may be measured in mW/cm², and gives a corresponding output to the processor that counts the output. The processor counts the energy to a predetermined quantity based on the activity of the final photopolymer formulation. The predetermined energy level may be determined empirically. Once the desired level has been reached the processor outputs to an audible output or other signal producing device to indicate the completion of the process. The sequence is repeated three times in total for back, imagewise and post exposures of the polymer sachet.

It is desirable that the device has a user interface that comprises operating devices, e.g. appropriate switches (as for example push buttons) and a signal producing apparatus, for example a piezo electric buzzer or other source of an audible signal. The buzzer or other audible signal source serves to produce an audible signal that allows the user to perform other tasks whilst waiting for the exposure to complete. The circuit diagram of FIG. 4 includes a buzzer.

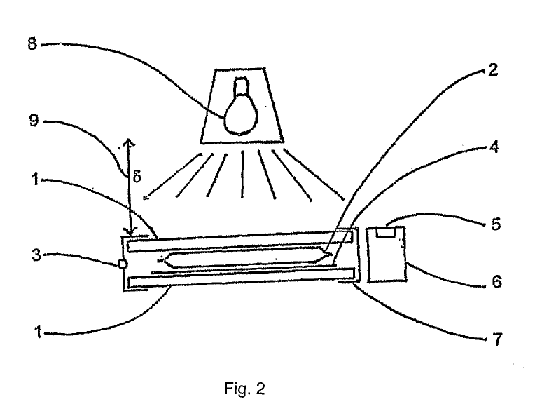

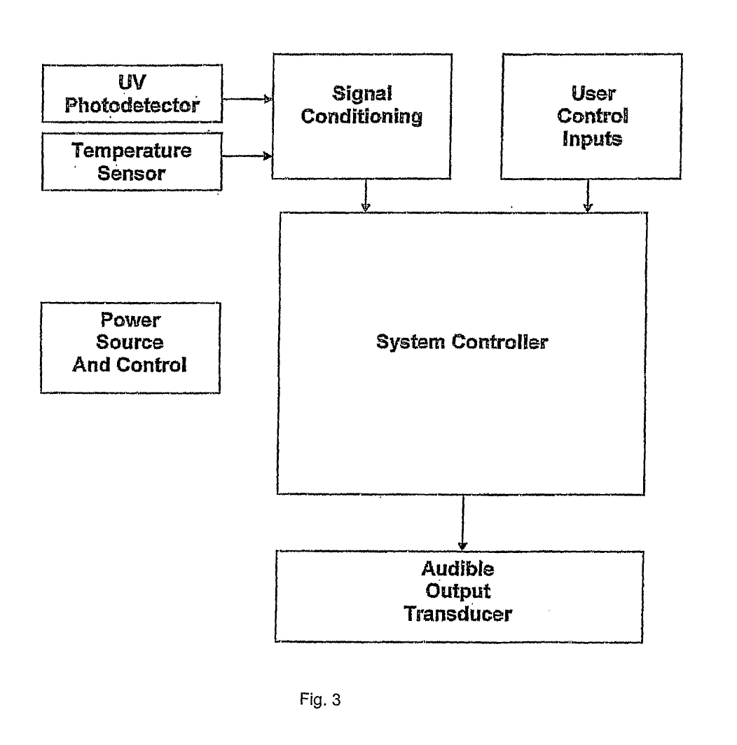

FIG. 3 illustrates a suitable timer apparatus whose circuit diagram is shown in FIG. 4. The illustrated circuit includes a PIC processor which, in the illustrated embodiment, is processor PIC16676 (Microchip Technology Inc, Chandler, Ariz.). A power source, e.g. a battery, and optionally a power source control, e.g. a switch, are operatively connected to a system controller. See FIG. 5C for a circuit diagram of a battery. A UV photodetector, for example a photodiode as previously described, outputs to the system controller, optionally through a signal conditioning means. A temperature sensor may also output to the system controller, but this is optional.

In use the system controller determines when the output from the UV photodetector has reached a specified level; where a temperature sensor is present, the specified level is determined partially on the basis of the output from the temperature sensor.

The apparatus includes also user control means which output to the system control. The user may use the control means to initiate operation of the system controller.

The typical operation of the electronic device is described as follows. The photopolymer container is placed over a photographic negative on one face of the ambient light curing exposure unit. The unit is closed, compressing the photopolymer container into a roughly cuboid shape. A first switch is operated to start monitoring the first exposure, or floor exposure. In one embodiment, the switch is in the form of a button which is held until an initiation signal is produced (e.g. a chirp is sounded), denoting that the monitoring has started; failure to produce a chirp or initiation signal indicates a low battery or other malfunction. This first exposure takes place with the clamp lying on a flat surface in ambient light conditions such that the photographic negative is at the bottom, nearest the work surface. By this means the bottom side of the plate is obscured from light and no curing can take place through the image side. At the end of this exposure a completion signal will be given, e.g. the piezo electric buzzer or other audible signal will sound, suitably at regular intervals for up to 5 minutes to signal the end of that cycle. The buzzer may be silenced at this time by pressing either button.

The clamp is then turned over so that the photographic negative is positioned at the top and a switch is operated to commence monitoring of the printing face exposure, e.g. a second button is pressed and held until a chirp is sounded or other initiation signal given. This second exposure will allow light through the negative, thus curing the plate imagewise. When a completion signal is given, e.g. the buzzer sounds, the exposure unit can be opened and the photopolymer container removed. The photopolymer container is then opened, e.g. cut around its perimeter using scissors, and the cut piece of plastic that was next to the negative is removed. The plate is then washed out by hand. This must take place very soon after the final buzzer as curing will continue whilst exposed to ambient light. The cured plate is placed in wash out liquid and washed out, e.g. is placed in a tray of warm water and detergent and washed out using a soft brush. After being washed out the polymer plate is placed in tray of shallow water which may include certain mineral salts to improve washout and the timer apparatus is initiated again, this time to determine the appropriate time for post-exposure. After the buzzer goes off for a third time, the plate has been post exposed and is ready to be dried, mounted and used for printing.

It may be required that the user periodically calibrates the dark level. This is done by covering the light sensor and pressing both buttons for five seconds. It has been found that a small processor is required to monitor the UV light levels and to handle the user interface. A suitable processor is that from the Microchip range of PIC processors. This specific processor chosen has an A to D interface for connection to the photodiode and is flash programmable. It has a standby current consumption of 10 nA and a running current of 10 uA (at 32 KHz).

It is a further development of embodiments of this invention is that the photopolymer has been modified to improve its usability in both sunlight and artificial ambient light. In this respect, it is desirable that the photopolymer reacts under ambient artificial light with sufficient speed to cure to a suitable depth in a reasonable period of time such that a user can complete each stage of its operation without excessive waiting, whilst at the same being stable in manufacture, transit and in use.

Typically the required wavelength. to activate photopolymer resin is in the region of 340 nm-365 nm. The peak wavelength however of natural and artificial light is typically higher, being >350 nm and also in the visible part of the electromagnetic spectrum. For this reason it is an adaptation of this invention that the photopolymer is modified to contain photoinitiators that exhibit absorbance band in both the UV and near visible region of the electromagnetic spectrum.

It is the case, therefore, that ambient artificial light emitted from light bulbs and fluorescent tubes has a peak wavelength that is higher than the light produced by actinic fluorescent tubes commonly used in photopolymer exposure units. The typical intensity produced by an artificial light sources in the UVA region is between 0.5-4.0 mW/cm². To enable the photoinitiators in the photopolymer to react when solely being irradiated by artificial ambient light it is necessary to utilise photoinitiators that are activated at a higher wavelength, typically 370-410 nm, e.g. an acylated phosphine oxide and more particularly a BAPO (bis-acylphosphine oxide). A mixture of photoinitiators may provide a suitable balance of properties.

Acylated phosphine oxides typically exhibit extinction coefficient maxima in the far UV to near visible region of the electromagnetic spectra, typically 390-420 nm. The inclusion of this type of initiator in the formulation allows the product to cure both under UV and ambient light. The inclusion of these types of photoinitiators can be as a blend with other types to ensure activity in both the UV-A and the near visible region of the electromagnetic spectrum. A typical example of a blend is Irgacure® 2022, a liquid blend of bisacyl phosphine oxide and alpha hydroxy ketone produced and marketed by Ciba Geigy.

In general terms, aromatic bisacylated phosphine oxides will prove effective as a range of initiators that will afford coverage across the region of 370-440 nm of the electromagnetic spectrum; additional examples are Lucerine (BAPO-1; BASF), and bis(2,4,6-trimethylbenzoyl)phenyl phosphine oxide (BAPO-3) and their commercially available blends. Furthermore, the photoinitiator may comprise a mixture of compounds, for example a mixture of one or more of the above named compounds.

Alternatively it is possible to use organometallic-based visible photoinitiators e.g. Irgacure 784. The use of these products is however difficult due to the enhanced activity in the visible region of the electromagnetic spectrum. The initiators also are readily oxidised in the presence of atmospheric oxygen.

Additionally, the resin preparation may contain any one or more of a range of further performance-enhancing additives including, for example, esters of acrylic or methacrylic acid, stabilisers, defoamers, dyes and high molecular weight fatty acids; the fatty acids, for example myristic acid, are particularly effective in ensuring a dry, tack-free surface after post-curing of the washed plate

The photopolymer resin used in the formulation can be manufactured to a variety of formulations by anyone skilled in the art. As discussed, the inclusion of a photoinitiator that has the ability to absorb in the both the UV and visible regions of the electromagnetic spectrum is the key to a good product. The level of the photoinitiator that can be of the types disclosed can be broadly at in an amount of, for example, 0.01%-10% and more typically at levels of 0.01% to 4%, the percentages being calculated by weight of the total liquid photopolymer. Often the amount of photoinitiator is from 0.01% to 1%, e.g. 0.02% to 1%, such as e.g. 0.02% to 0.5%, as in the case of compositions containing 0.03% or more, e.g. 0.04% or more, and/or no more than 0.2%, e.g. no more than 0.1%.

It is desirable that the cure speed of the reaction is adjusted so that it will work satisfactorily in varied light conditions. For example, the minimum exposure time may be selected to give 3 minutes main exposure (through the masking element) in direct strong sunlight and the maximum required exposure may be selected to give 15 minutes main exposure (through the masking element) in low level ambient light within offices after dark. This variation in cure speed may achieved by selecting the proportion of photoinitiator by empirical experimentation. It is contemplated that an alternative technique would be to include one or more photoabsorbers in the resin as well as one or more photoinitiators and to balance the levels of the photoinitiators and photoabsorbers in the polymer at amounts where the desired curing times were observed; again, the levels may be determined empirically. In any event, the cure speed is selected such that it enables the photopolymer container to be handled in ambient light for long enough to assemble in the clamp, typically just under a minute, without deleterious effects on the plate, whilst at the same time achieving a finished plate within 15 minutes in low level ambient light.

Normal photopolymer used in the manufacture of hands stamps and flexographic printing plates has a reactivity, measured by determining the depth of cure in mm when exposed to light of a typical intensity of between 6-12 mW/cm² at a wavelength of 340 nm for 30 seconds, giving 0.8-1.4 mm of cured polymer. It is also desirable that the polymer in the pre-packaged container has a reactivity that is consistent with that disclosed above when exposed to light of an intensity of 1 mW/cm² at a wavelength 315-400 nm for 120 seconds.

The liquid photopolymer preparation may comprise any readily available photopolymer preparation of a type that would be well known the person skilled in the art. Typical liquid photopolymers may include, for example, unsaturated polyester resins, unsaturated polyurethane resins, unsaturated polyamide resins and unsaturated poly(meth)acrylate resins, for example polyether urethane polymers, or polyether polyester urethane copolymers such as polyether polyester urethane methacrylate photopolymers.

Various aspects of the invention will now be particularly described with reference to the following examples:

### EXAMPLES

### Example 1

To a mixture of 1500 parts by weight of polyether polyol (2.0 terminal hydroxyl groups per molecule and an average molecular weight of 3600), 1 part of butylated hydroxy toluene (BHT), 10 parts of triphenyl phosphite and 100 ppm of dibutyl tin dilaurate (DBTDL) was added 120 parts of by weight of 2,4-toluene diisocyanate (TDI). The resulting mixture was reacted at 80° C. for 3.0 hours to obtain a polyurethane oligomer having isocyanate groups at both ends of the molecule. To this were added 35 parts by weight of hydroxypropyl methacrylate and 20 ppm of dibutyl tin dilaurate (DBTDL) after which the reaction mixture was stirred at 70° C. until no residual isocyanate could be determined by titration with di-n-butylamine. To 1500 grams of the foregoing prepolymer were added 625 grams of polypropylene glycol monomethacrylate and 125 grams of hydroxypropyl methacrylate (HPMA) and 2 grams of hydroxy cyclohexyl phenyl ketone and 1 gram of bis(2,4,6-trimethylbenzoyl)-phenylphosphine oxide and 0.1 gram of bis(η⁵-2,4-cyclopentadien-1-yl)-bis(2,6-difluoro-3-(1H-pyrrol-1-yl)-phenyl) titanium. The resulting mixture was mixed for 1 hour to obtain a photosensitive resin composition.

The resin was then discharged into a sachet with a fill level to ensure a plate thickness of 2.55 mm. The sachet was then compressed in a clamp and exposed through a photomask under a 100 W bulb for 3 minutes on the back exposure and 10 minutes through the photomask. This yielded a cured photopolymer plate with a floor of 1.5 mm.

### Example 2

To a mixture of 1500 parts by weight of polyether polyol (2.0 terminal hydroxyl groups per molecule and an average molecular weight of 3600), 1 parts of butylated hydroxy toluene (BHT), 10 parts of triphenyl phosphite and 100 ppm of dibutyl tin dilaurate (DBTDL) was added 120 parts of by weight of 2,4-toluene diisocyanate (TDI). The resulting mixture was reacted at 80° C. for 3.0 hours to obtain a polyurethane oligomer having isocyanate groups at both ends of the molecule. To this were added 35 parts by weight of hydroxypropyl methacrylate and 20 ppm of dibutyl tin dilaurate (DBTDL) after which the reaction mixture was stirred at 70° C. until no residual isocyanate could be determined by titration with di-n-butylamine. To 1500 grams of the foregoing prepolymer were added 625 grams of polypropylene glycol monomethacrylate and 125 grams of hydroxypropyl methacrylate (HPMA) and 2 grams of hydroxy cyclohexyl phenyl ketone and 1.5 gram of bis(2,4,6-trimethylbenzoyl)-phenylphosphine oxide and 0.5 gram of bis(η⁵-2,4-cyclopentadien-1-yl)-bis(2,6-difluoro-3-(1H-pyrrol-1-yl)-phenyl)titanium. And the resulting mixture was mixed for 1 hour to obtain a photosensitive resin composition.

The resin was then discharged into a sachet with a fill level to ensure a plate thickness of 2.55 mm. The sachet was then compressed in a clamp and exposed through a photomask under a 100 W bulb for 1 minutes on the back exposure and 6 minutes through the photomask. This yielded a cured photopolymer plate with a floor of 1.4 mm.

### Example 3

To a mixture of 1500 parts by weight of polyether polyol (2.0 terminal hydroxyl groups per molecule and an average molecular weight of 3600), 1 parts of butylated hydroxy toluene (BHT), 10 parts of triphenyl phosphite and 100 ppm of dibutyl tin dilaurate (DBTDL) was added 120 parts of by weight of 2,4-toluene diisocyanate (TDI). The resulting mixture was reacted at 80° C. for 3.0 hours to obtain a polyurethane oligomer having isocyanate groups at both ends of the molecule. To this were added 35 parts by weight of hydroxypropyl methacrylate and 20 ppm of dibutyl tin dilaurate (DBTDL) after which the reaction mixture was stirred at 70° C. until no residual isocyanate could be determined by titration with di-n-butylamine. To 1500 grams of the foregoing prepolymer were added 625 grams of polypropylene glycol monomethacrylate and 125 grams of hydroxypropyl methacrylate (HPMA) and 2 grams of hydroxy cyclohexyl phenyl ketone and 2.0 gram of bis(2,4,6-trimethylbenzoyl)-phenylphosphine oxide and 0.1 gram of bis(η⁵-2,4-cyclopentadien-1-yl)-bis(2,6-difluoro-3-(1H-pyrrol-1-yl)-phenyl)titanium. The resulting mixture was mixed for 1 hour to obtain a photosensitive resin composition.

The resin was then discharged into a sachet with a fill level to ensure a plate thickness of 2.55 mm. The sachet was then compressed in a clamp and exposed through a photomask under a 100 W bulb for 2 minutes on the back exposure and 8 minutes through the photomask. This yielded a cured photopolymer plate with a floor of 1.5 mm.

### Example 4

An A5 sized imagepac sachet that was 2.3 mm thick was placed over a photographic negative that is typically 0.1 mm thick, containing designs that would become the printed images for stamps. The sachet was closed in a glass clamp that was fitted with bearers that are 2.3 mm. The respective dimensions are such that the sachet was compressed completely and all entrapped air was displaced. The clamp was placed on a worktop during daylight conditions with additional normal office lighting, such that the negative was next to the worksurface. The combination of natural light through the windows and artificial light from the fluorescent tubes created enough intensity of light to cure the plate. A timer as previously described was provided. The button was pressed to start the first (floor) exposure, the buzzer went off 3 minutes and 30 seconds later and the clamp was reversed and the second button was depressed. The buzzer went off 9 minutes and 30 seconds later and the plate had now been exposed on both sides. The clamp was opened and the sachet was removed. The perimeter of the sachet was cut with scissors and the side that was next to the negative was removed to reveal the liquid polymer. The plate was washed out in a tray of warm water and detergent using a brush. The plate was placed in a tray of water and the second button was depressed again. When the buzzer went off for a third time the plate was removed and the plate was dried. It was mounted to a stamping device (such as a self inker) and the resulting image was found to be faultless.

### Example 5

An imagepac xtra sachet that was A6 sized and that was 2.3 mm thick was placed over a photographic negative that is typically 0.1 mm thick, containing designs that would become the printed images for stamps. The sachet was laid over the negative so that the backing sheet surface was facing up. The glass clamp was fitted with bearers that are 2.3 mm thick. The sachet was closed over the assembly. The respective dimensions are such that the sachet was compressed completely and all entrapped air was evacuated. The clamp was placed on a worktop during daylight conditions with additional normal office lighting, such that the negative was next to the worksurface. The combination of natural light through the windows and artificial light from the fluorescent tubes created enough intensity of light to cure the plate. A timer as previously described was provided. The button was pressed to start the first (floor) exposure, the buzzer went off 2 minutes and 48 seconds later and the clamp was reversed and the second button was depressed. The buzzer went off 6 minutes and 37 seconds later and the plate had now been exposed on both sides. The clamp was opened and the sachet was removed. The perimeter of the sachet was cut with scissors and the side that was next to the negative was removed to reveal the liquid polymer. The plate was washed out in a tray of warm water and detergent using a brush. The plate was placed in a tray of water and the second button was depressed again. When the buzzer went off for a third time the plate was removed and the plate was dried. It was mounted to a stamping device (such as a self inker) and the resulting image was found to be faultless.

As previously discussed, the present invention shows significant advantages over the existing methodology in that there is no requirement for the user to purchase an expensive exposure unit that would contain electrical wiring and fluorescent tubes.

### Example 6

The pre-packaged container is removed from its light proof storage box. This container of photocurable resin is laid over a masking element, or negative, and is inserted in a light transmitting clamp to compress it evenly. The sachet is compressed between two light transmitting sheets of the clamp, typically glass sheets, which have spacers, or bearers, at their edges to ensure that the liquid resin container will take a planar parallel dimension during exposure to the light. By selecting the fill of liquid resin in the container it is possible to ensure that there will be adequate pressure on the side walls when the clamp is closed to force all entrapped air out. For convenience a clip is inserted over the clamp to ensure that the photocurable resin container is under compression and no air can be present between the container, the negative and the walls of the clamp.

It will be appreciated from the aforegoing that this invention describes amongst other things an exposure apparatus comprising a light measuring device and a light transmitting clamp designed to compress a photocurable (photopolymer) package for use in manufacture of a hand stamp plate, the package typically consisting of a sachet containing a liquid photopolymer. The liquid photopolymer is specifically engineered to cure under ambient lighting conditions eliminating the requirement for fluorescent tubes to create the UV light to cure the photopolymer. The light measuring device is designed to inform the user of the required exposure time for the printing plate.

1-76. (canceled)

77. A liquid photopolymer adapted to form a polymer printing plate and containing a photoinitiator which is activated by light at a wavelength of at least 370 nm.

78. A liquid photopolymer of claim 77, which contains a photoinitiator selected from a bis-acylphosphineoxide photoinitiator and an organometallic-based visible light photoinitiator.

79. A liquid photopolymer of claim 78, wherein the organometallic-based visible light photoinitator is Irgacure 784.

80. A liquid photopolymer of claim 77 which has a reactivity of about 0.8 to 1.2 mm when exposed to light of an intensity of 1 mW/cm² at a wavelength 315-400 nm for 120 seconds.

81. A liquid photopolymer of claim 77 which has a viscosity of 2,000-50,000 cps.

82. A liquid photopolymer of claim 77 which comprises an unsaturated polyurethane resin.

83. A liquid photopolymer of claim 82 which comprises a polyether urethane polymer.

84. A liquid photopolymer of claim 82 which comprises a polyether polyester urethane copolymer.

85. A liquid photopolymer of claim 84 which comprises a polyether polyester urethane methacrylate polymer.

86. A liquid photopolymer of claim 77, which is comprised in a photopolymer package, said package comprising a light-transmitting envelope in which the photopolymer is contained, wherein at least a major wall of the envelope being releasable from the polymer once the polymer has been cured.

87. A liquid photopolymer of claim 77, when comprised in a photopolymer package, the package comprising a sealed sachet, wherein the liquid photopolymer is contained in the sachet the liquid photopolymer containing a photoinitiator which is activated by light at a wavelength of at least 370 nm.

88. A method of curing liquid photopolymer, the method being in the formation of a printing plate and comprising exposing the liquid photopolymer to ambient light.

89. A method of claim 88 which comprises the steps of:
(a) uniformly exposing a first face of a container of the liquid photopolymer to form a floor; and then
(b) imagewise exposing a second face of the liquid photopolymer container to form a printing surface.

90. A method of claim 88, wherein the printing plate is a hand stamp plate and the method further comprises assembling a hand stamp from the plate.

91. A method of claim 90, which further comprises the steps of:
(a) clamping the photopolymer of claim 10 and a photographic negative in a light transmitting clamp having opposed faces, the negative being interposed between the package and one of the opposed faces;
(b) placing the resultant assembly on a work surface such that the negative is adjacent to the work surface and allowing the upper surface of the assembly to be irradiated with light to form a floor;
(c) inverting the assembly to imagewise expose the package;
(d) cutting and washing the resultant cured plate to remove non-irradiated material;
(e) post-exposing the washed out plate to remove surface tackiness; and
(f) drying the plate.

92. A method of claim 91 wherein the radiation comprises daylight or artificial ambient light.

93. A method of claim 91 wherein the step of washing is performed using a wash out liquid comprising an aqueous medium containing a surfactant wherein the surfactant comprises an alkyl sulphate, a dialkyl sulphosuccinate, a triethanolamine alkyl sulphate, a polyoxyethylene alkylphenylether sulphonic acid sodium salt or a polyoxyethylene alkylbenzene sulphonic acid triethanolamine salt.

94. A method of claim 91 wherein the plate is post-exposed by the use of ambient natural or artificial light.

95. A method claim 93 wherein the post-exposure is carried out under water.

96. A photopolymer adapted to form a polymer printing plate and containing a photoinitiator which is activated by light at a wavelength of at least 370 nm.

97. A photopolymer of claim 96, which contains a photoinitiator selected from a bis-acylphosphineoxide photoinitiator and an organometallic-based visible light photoinitiator.

98. A photopolymer of claim 97, wherein the organometallic-based visible light photoinitiator is Irgacure 784.

99. A photopolymer of claim 96 which comprises a resin selected from the group consisting of an unsaturated polyurethane resin, an unsaturated polyester resin, an unsaturated polyamide resin and an unsaturated poly(meth)acrylate resin.

100. A photopolymer of claim 99 which comprises a polyether urethane polymer.

101. A photopolymer of claim 99 which comprises a polyether polyester urethane copolymer.

102. A photopolymer of claim 101 which comprises a polyether polyester urethane methacrylate polymer.

103. A photopolymer of claim 96, when comprised in a photopolymer package which comprises a light-transmitting envelope in which the photopolymer is contained, wherein at least a major wall of the envelope being releasable from the polymer once the polymer has been cured.

104. A method of curing photopolymer, the method being in the formation of a printing plate and comprising exposing the photopolymer to ambient light.

105. A method of claim 104, wherein the printing plate is a hand stamp plate and the method further comprises assembling a hand stamp from the plate.

106. A method of claim 104 wherein the photopolymer is exposed to daylight or artificial ambient light.
